(19) United States
(12) Patent Application Publication
(10) Pub. No.: US 2006/0186525 A1
(43) Pub. Date: Aug. 24, 2006

(54) Electronic component with stacked semiconductor chips and method for producing the same

(76) Inventors: Horst Theuss, Wenzenbach (DE); Michael Weber, Mainburg (DE)

Correspondence Address: EDELL, SHAPIRO & FINNAN, LLC, 1901 RESEARCH BLVD., SUITE 400, ROCKVILLE, MD, 20850, US

(21) Appl. No.: 11/345,667

(22) Filed: Feb. 2, 2006

(30) Foreign Application Priority Data
Feb. 2, 2005 (EP) 05002187.2-2203

(51) Int. Cl. H01L 23/02

(52) U.S. Cl. 257/686

(57) ABSTRACT

A semiconductor component includes a first module component and a second module component stacked one on top of the other, and a spacer arranged between the two module components. The module components are electrically connected to one another and/or to a higher-level circuit carrier by connecting elements. At at least one point, the spacing between the spacer and a contact area of the lower of the two module components is kept very small or the spacer overlaps and partially covers the contact area.

### CROSS REFERENCE TO RELATED APPLICATIONS

This application claims priority under 35 U.S.C. §119 to European Patent Application No. EP 05002187.2-2203, filed on Feb. 2, 2005, and titled “Electronic Component With Stacked Semiconductor Chips And Method For Its Production,” the entire contents of which are hereby incorporated by reference.

### FIELD OF THE INVENTION

The invention relates to an electronic component with stacked semiconductor chips and to methods for producing such an electronic component.

### BACKGROUND

U.S. patent Publication No. 2003/0178710 A1 and U.S. Pat. No. 5,323,060 disclose electronic components in which portions of a semiconductor wafer are connected to a plastic carrier, which is applied to a semiconductor chip by what is known as “tape” technology. Subsequently, a further semiconductor chip is placed on the region of plastic by an individual pick-and-place technique. Finally, the semiconductor chip positioned on top is contacted by a wire bonding method. As an alternative to the use of a “tape” method, a thick layer of adhesive may also be applied to the lower semiconductor chip by dispensing.

A disadvantage of the methods known in the prior art is that the individual pick-and-place methods are very laborious. Furthermore, the placement accuracy of the spacer on the lower semiconductor chip is limited, so that there are sometimes problems with the stability of the two chips deposited one on top of the other. Furthermore, there is the risk of wire bonds used for contacting purposes or molds used for production purposes being soiled by stray adhesive.

### SUMMARY

The invention provides a stable and reliable chip stack with the lowest possible costs and avoids the disadvantages of the methods and devices that are known in the prior art. According to the invention, a semiconductor component which comprises two module components stacked one on top of the other, for example in the form of semiconductor chips, is provided. The semiconductor chips are electrically connected to each other and/or to a higher-level circuit carrier by connecting elements.

According to one embodiment, outer side surfaces of the spacer are spaced at a distance from the contact areas of the lower module component. At at least one point, the distance d between the outer side surface of the spacer and a contact area of the lower module component is 0 μm<d<80 μm, preferably 0 μm<d<40 μm.

The spacer and the outer side surfaces of the spacer are, therefore, not in physical or mechanical contact with the contact area. In a further embodiment, the spacer is positioned in the central regions of the active surface of the lower module component so that the outer side surface of the spacer lies at a distance d from all of the contact areas on the active surface of the lower module component.

A distance of greater than 0 microns ensures that the spacer is not in physical contact with the contact area. This provides a larger available area for producing the electrical connection to the contact area. The electrical connection may be provided by a bond wire. A distance of less than 80 microns or less than 40 microns has the advantage that the spacer has a large area. This enables the upper module component to be reliably supported and provides additional support to the structure during the connection of the contact elements to the upper module component after it has been mounted on the spacer to form the stack.

In a further embodiment, at at least one point, the distance d between the outer side surface of the spacer and a contact area of the lower module component is 0 μm<d<20 μm, preferably 0 μm<d<10 μm, more preferably 0 μm<d<5 μm, and even more preferably 0μm<d<1 μm. This further increases the areal extent of the spacer and improves the stability of the stack. A smaller distance is advantageous for an embodiment in which the upper module component is areally or laterally larger than the lower module component.

A chip stack of this type has the advantage that even a region over a surface structure of the lower semiconductor chip can be used for a spacer between the semiconductor chips, and it is consequently possible for connecting elements to be attached between the two module components in the edge regions outside the surface structure of the lower semiconductor chip. For this purpose, the height of the spacer is advantageously adapted to the space requirement of the connecting elements arranged between the module components.

The spacer according to the invention has walls which are preferably produced from a photo-patternable material that has the required thicknesses of several 10 μm. The spacer may already be applied in a previous process to a semiconductor chip that is being used.

The spacer may comprise at least one wall of a photo-patternable material, the wall having a breadth. The outer side surfaces of the at least one wall provide the outer side surfaces of the spacer in this case. This structure had the advantage that the upper module component may be more reliably attached since rounding or bowing of the upper surface of a larger mass is avoided. The wall providing the spacer may comprise a continuous loop.

In a further embodiment, the semiconductor component with a first module component and with a second module component is provided in which a spacer is arranged between the two module components stacked one on top of the other. The first and second module components are electrically connected to one another and/or to a higher-level circuit carrier by connecting elements. At at least one point, the spacer covers a contact area of the lower module component while leaving a partial region of the contact area free. This further increases the areal extent of the spacer and further increases the stability of the stack.

In a further embodiment, at at least one point in the spacer, a channel leads from the contact area to an edge region of the lower module component, with a partial region of a surface of the lower module component being left free at the bottom of the channel. The channel enables the electrical connection to be led from the contact area over the edge of the lower module component within the channel. This has the advantage that the electrical connections may be easily produced while the spacer provides support to the upper module component under the edge region. This is advantageous when contacts are produced to contact areas of the upper module component positioned in the edge region.

In a further embodiment, a contact area of the lower module component is surrounded at least on one side by a partial region of the spacer in the manner of a finger. The partial region of the spacer in the manner of a finger may be spaced at a distance from the contact area. At at least one point, the spacing distance d between the outer side surface of the spacer and a contact area of the lower module component is 0 μm<d<80 μm, preferably 0 μm≦d≦40 μm.

A distance of greater than 0 microns ensures that the spacer is not in physical contact with the contact area. This provides a larger available area for producing the electrical connection to the contact area. The electrical connection may be provided by a bond wire. A distance of less than 80 microns or less than 40 microns has the advantage that the spacer has a large area. This enables the upper module component to be reliably supported and provides additional support to the structure during the connection of the contact elements to the upper module component after it has been mounted on the spacer to form the stack.

The wall structure of the spacer is preferably produced from a polymer which can be applied by a spin-coating process for a number of semiconductor chip positions arranged on a wafer. The patterning then also takes place in a parallel process for many semiconductor chips simultaneously by appropriate photolithography. Consequently, in a preferred embodiment of the invention, the spatially coupled cavity resonator region has a cured photoresistive pattern, which is spatially adapted to the surface structure, and in particular to the contact areas of the semiconductor chips, and forms the spacer between two module components stacked one on top of the other. This advantageously saves material and assembly time during stacking of the module components that would otherwise have to be used preparing and introducing spacer elements when stacking individual semiconductor chips.

The distance-maintaining spacer is arranged at the center of a module component or semiconductor chip, and the connecting elements, such as bonding wires for instance, are attached on the edge regions surrounding the center. Depending on the size of the module components to be stacked, these connecting elements are respectively applied in each case to the upper side of the module component lying under them before the stacking of the next module component to be stacked or, if the surface-area extent of the module components in the stack does not successively decrease, these connecting elements may also be mounted after the stacked module component is applied. In this respect, the point in time in the production process at which the connecting elements are introduced in relation to the individual module components also depends on the type of connecting elements.

For instance, connecting elements in the form of contact vias through the semiconductor or ceramic substrates may already be connected to one another during the surface mounting of the individual module components one on top of the other. If, on the other hand, the module components have bonding wires as connecting elements, these are applied from contact areas in the edge regions of the module components to edge regions of a higher-level circuit carrier after the respective fixing of one of the module components. If, in a preferred embodiment of the invention, the module components have flip-chip contacts as connecting elements, these can likewise be connected along with the surface mounting of the module components to corresponding connecting structures of module components arranged underneath.

For stacking the module components one on top of the other, double-sided adhesive films may be used. Double-sided adhesive films of this type have the advantage that they do not have to be specially structured in the same way as conventional adhesives to obtain the adhesive function. Furthermore, they have the advantage that there is no longer any need for an adhesive to be dispensed onto corresponding areas that are to be connected. With a double-sided adhesive film of this type, the assembly costs of a semiconductor component of this type can be reduced considerably.

A method for producing a semiconductor component from module components includes the following operations. First, a higher-level circuit carrier for the semiconductor component is produced with electrical terminal areas for stacked module components. This circuit carrier may be of a multi-layered configuration and have on its upper side the terminal areas for the stacked module components, while on its underside or back side there are external contact areas, to which further electrical lines can be connected. From the terminal areas on the upper side of the higher-level circuit carrier, contact vias may lead to the external contact areas on the underside of the circuit carrier.

At a time and place that is independent of the production of the higher-level circuit carrier, the module components are produced, with a base module component being provided. Subsequently, the module components are stacked on the circuit carrier.

Depending on the surface-area extent of the module components, the module components are interconnected to one another and to the circuit carrier by producing electrical connections by connecting elements directly after individual module components are attached or after the entire stack is completed. Subsequently, the circuit carrier with the stacked module components can be introduced into a housing. This housing may represent the housing of a mobile telephone.

In a preferred way of implementing the method, the housing is formed from a plastic molding compound into which the semiconductor component on the circuit carrier is embedded.

An advantage of this method is that, as a result, a semiconductor component with spatially smaller dimensions than previously customary semiconductor modules can be produced. Furthermore, the method has the advantage that it is possible to dispense with previously customary components such as spacers. In addition, this method also has the advantage that semiconductor components can be produced in an extremely confined space with a reduced reject rate.

A further method for producing a semiconductor component includes providing a semiconductor wafer with a plurality of semiconductor chip positions and an active surface, each semiconductor chip position having an active surface with contact areas. A photo-patternable material is applied to an active surface of the wafer and the photo-patternable material is patterned to form a spacer on the active surface in each semiconductor position. The semiconductor chip positions are separated from the wafer to provide a plurality of lower module components, each having a spacer positioned on the active surface.

A plurality of upper module components are provided each having an active surface with contact areas and a higher-level circuit carrier is provided. A lower module component is mounted on the higher-level circuit carrier, and electrical connections between the lower module carrier and the higher-level circuit carrier are produced. The passive surface of the lower module component is mounted on the higher-level circuit carrier so that the spacer, active surface and contact areas face upwards away from the higher-level circuit carrier.

For the upper and the lower module components, the active surface is distinguished in that it comprises integrated circuit elements and contact areas which allow electrical access to the integrated circuit elements. Each module component also has an opposing passive surface which is free from integrated circuit elements.

An upper module carrier is mounted on the spacer of the lower module carrier and electrical connections between the upper module component and the higher-level circuit carrier are produced. The passive surface of the upper module is mounted on the spacer of the lower module component. The contact areas and the active surface of the upper module component, therefore, face upwards away from the higher-level circuit carrier and may be easily accessed to produce the electrical connections. The upper module component, lower module component and electrical connections may then be embedded in plastic encapsulation compound to provide a semiconductor module.

In summary, the solution according to the invention for creating spacers uses a polymer applied in what is known as the front-end process in order to produce a semiconductor module stack inexpensively. In particular, the spacer may be produced for a plurality of semiconductor chips at the wafer level. In addition to simplifying the production process of the spacer, the assembly process of the module is simplified since the lower module is provided with a spacer on the active surface. The upper module may then be mounted on the spacer. A separate mounting process for the spacer is avoided.

The polymer of the spacer may be the one that is used as a wall structure, in particular in the case of BAW filters, to create a cavity wall around the active chip area in the form of a piezo resonator. The polymer may be a photo resist material, such as the commercially available material known as SU8. This allows a significant reduction in the overall size of the component to be achieved in a simple way.

The stability of module components put together in such a way can be increased considerably in comparison with the prior art. This is because such a spacer according to the invention can even be formed around the terminal contact areas of a semiconductor chip, leaving only a small, narrow, laterally leading-away channel for the connecting elements. In this case, very small spacings of a few micrometers (μm) can be achieved between the contact areas. This produces a large supporting area on the spacer. It also achieves the effect that the two module components only have a slight tendency to tilt.

In addition, the photoresist used particularly advantageously for production is significantly harder and less flexible than the adhesive tapes known in the prior art. This considerably increases the immunity to failure of the internal contacting points.

Apart from wire bonding, other known possible means of establishing internal connections may be used for the stacking or for producing connections of the module components with respect to one another and with respect to a higher-level circuit carrier, for example by solder balls or flip-chip related mechanisms of interconnection. Even via holes would constitute a further advancement. Furthermore, hybrid technologies may also be advantageous. Hybrid technologies in this case mean flip-chip technology combined with a solder-ball technique and/or with a wire bonding technique.

The above and still further objects, features and advantages of the present invention will become apparent upon consideration of the following definitions, descriptions and descriptive figures of specific embodiments thereof wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

FIG. 1 shows a schematic cross section through a semiconductor component according to a first embodiment of the invention.

FIG. 2 shows a partial region of the semiconductor component from FIG. 1 in plan view.

FIGS. 3-7 illustrate partial steps in the production of the semiconductor component according to FIGS. 1 and 2.

### DETAILED DESCRIPTION

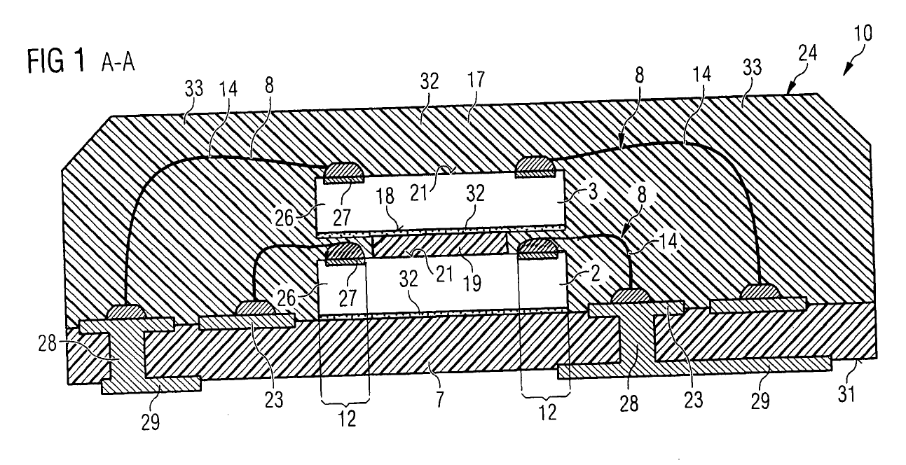

FIG. 1 shows a schematic cross section through a semiconductor module 10 according to a first embodiment of the invention. The semiconductor module 10 is arranged on a higher-level circuit carrier 7. The semiconductor module 10 represents a stack with a lower module component 2, which serves as a base module component, and with an upper module component 3, which is constructed in the same manner as the base module component 2. Both the module component 2 and the module component 3 are semiconductor chips with circuit structures that are not shown in detail here.

Arranged between the module component 2 and the module component 3 is a spacer 19, which is formed as a hardened photoresistive pattern. In this exemplary embodiment, the spacer 19 is about 40 to 50 ∥m high. In other exemplary embodiments, heights of from 20 to 40 μm or 50 μm to 80 μm or even 100 μm are advantageously used, depending on how much space is required for the connecting elements 8.

This photoresistive pattern on the base module component 2 lies against the back or passive side 18 of the stacked module component 3. Consequently, connecting elements 8, which are formed here as bonding wires, may be arranged in the edge region 12 of the module components 2, 3.

For this purpose, contact areas 27 are arranged at the edge regions 12 of the upper side 21 of the base module component 2. The upper side 21 is the active surface and comprises integrated circuit elements which are not illustrated in the figures. These contact areas 27 are connected by bonding wires 14 to terminal areas 23 of the circuit carrier 7. These terminal areas 23 are connected to external contact areas 29 on the underside 31 of the circuit carrier 7 by contact vias 28 through the circuit carrier 7.

As can be seen particularly well in FIG. 1, the spacer 19 extends up to very near the contact areas 27.

The module component 2 and the module component 3 are coupled to each other by the circuit carrier 7 and their signals are supplied to the external contact areas 29 of the circuit carrier 7 by the contact vias 28. To protect the bonding wires 14, the semiconductor module is embedded in a plastic package molding compound.

The module components 2 and 3 are mechanically connected to one another and to the circuit carrier 7 by correspondingly cut-to-size double-sided adhesive films 32. Depending on the application, the housing 24 may also comprise a housing structure that can be latched onto the circuit carrier 7 or formed from a plastic package molding compound 33.

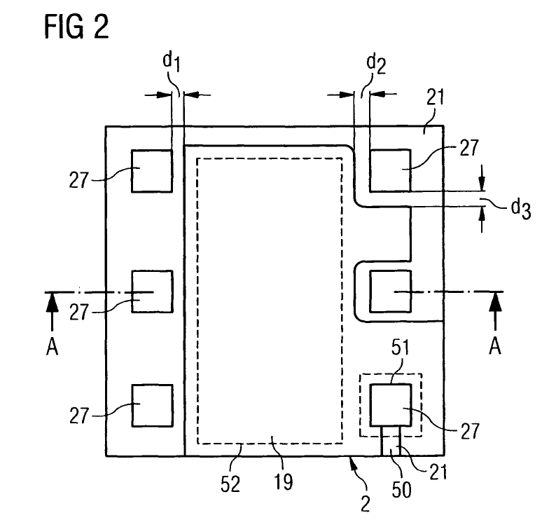

FIG. 2 shows a partial region of the semiconductor module 10 from FIG. 1 in plan view, to be specific the plan view of the lower module component 2 with the module component 3 removed and the film 32 removed.

As can be seen particularly well in this view, the spacing d1 between the left-hand contact areas 27 and the spacer 19 is very small, to be specific about 5 μm. The spacing can be kept very small, even down to about 1 μm and below. Even overlap of the contact area 27 and spacer 19 is conceivable, so that sealing between the edge region of the contact areas 27 and the surface 21 of the semiconductor chip 2 can be achieved. If an isolator is used for the spacer 19, it is even possible to dispense with a previously necessary passivation layer, since the spacer 19 then takes over its passivation function. As a result, contamination of the surface 21 with radicals in the air is prevented.

On the right-hand side of the semiconductor chip 2, the spacer is shown with further variants of the configuration of the spacer 19 in the region around contact areas 27. In the top right-hand corner and in the center of the semiconductor chip 2, the spacer 19 extends with a spacing d2 and d3 respectively around the contact areas 27 in the manner of a finger.

Here, the spacings d1, d2 and d3 are about 5 μm. They can also be chosen to be greater, for example 10 μm or 20 μm, or else up to 40 μm or 80 μm, whereby it is also possible for the spacer to be created by imprecise working.

It is still more advantageous to lead the spacer 19 around the contact area 27, as is shown in the bottom right-hand corner of the semiconductor chip 2, with sealing and passivation taking place. This then leaves only a narrow channel 50 with a width of about 20-30 μm, through which a bonding wire can be placed. The bonding can then also be performed through a window 51 in the spacer 19, the width of which is kept just large enough that the bonding tool can create the bonding connection with the tip of its stylus. Although the small surface of the semiconductor chip 2 that is not covered by the spacer 19 is then not passivated, this is not noticeable as a result of its great distance from the active components of the integrated circuit on the semiconductor chip. The location of the active components is marked in FIG. 2 by a dashed line 52.

Precisely when the spacer 19 is formed into the edge region of the semiconductor chip 2, significant advantages are obtained with regard to the stability of the arrangement when, subsequently, the upper-lying semiconductor chip 3 is bonded. This is because the spacer 19 lies with its corresponding partial regions directly underneath the contact areas 27 of the chip as a support, through which the flux of force passes during the bonding of the upper bonding wires 14. This reduces the risk of microcracks that exists when bonding the contact areas situated on the left in FIG. I and FIG. 2. This is because the region of the upper semiconductor chip 3 protruding above the spacer 19 is subjected to flexural loading during the bonding, as a result of which microcracks are provoked in its surface 21 at the point of greatest tensile loading.

In the case of the contact areas of the upper semiconductor chip 3 situated on the right in FIG. 1 and FIG. 2, this risk is reduced by the supporting function of the spacer 19.

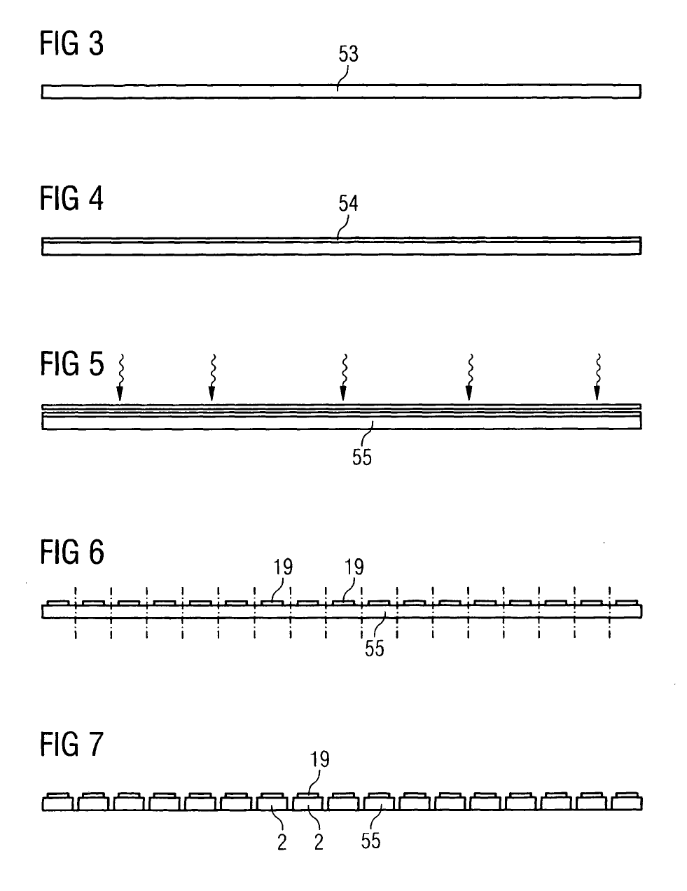

FIGS. 3-7 illustrate a method for producing the electronic components according to the invention. First, according to FIG. 3, a semiconductor wafer 53 with semiconductor chip positions which have circuit structures in predetermined surface regions is provided. According to FIG. 4, a layer of plastic 54 is applied to the semiconductor wafer, from which plastic, according to FIGS. 5 and 6, the spacers 19 are structured by using a photolithographic process. This layer of plastic 54 is only a few micrometers thick and may have a thickness of up to 200 μm.

Before the semiconductor wafer is separated into first semiconductor chips by sawing, an adhesive film 55 is applied to the back side of the semiconductor chip. This adhesive film 55 ensures that the semiconductor wafer 53 is not displaced during the later separation into first semiconductor chips 2 with attached adhesive film. After the separation of the semiconductor wafer 53 into first semiconductor chips 2 with attached adhesive film 55 according to FIG. 2, the semiconductor chips 2 are applied to a metal frame (not shown here) for flat-conductor-free housings with the semiconductor chip 2 adhesively attached and the adhesive film 55 cured on the back side of the semiconductor chip 2.

Here, too, the adhesive film 55 serves the purpose of fixing the semiconductor chip 2, to be precise on inner areas of external contacts. This fixing assists secure bonding of the contact areas on the upper side of the semiconductor chip to contact terminal areas on the inner areas of the external contacts. The further process steps for producing the semiconductor module 10 are not shown in separate figures.

The contact terminal areas may have a bondable refinement layer with respect to the metals of the external contacts. Refinement layers of this type comprise gold or alloys of gold. They assist the production of bonding connections between contact areas on the upper side of the semiconductor chip and inner areas of external contacts of the metal frame.

After that, the cavity frame is covered with the second semiconductor chip. For this purpose, the second semiconductor chip likewise has on its back side an adhesive film, which corresponds to the adhesive film of the first semiconductor chip. This adhesive film on the back side of the second semiconductor chip ensures that unevennesses of the spacer are compensated. After attaching the second semiconductor chip, the semiconductor chips with the bonding wires may be packaged in a plastic package molding compound. This involves embedding the bonding wires, the semiconductor chips and the spacer 19 in the plastic molding compound. Only the external contacts on the underside of the electronic components remain freely accessible.

Once the semiconductor chips have been packaged in the plastic package molding compound, the metal frame, which has received a plurality of electronic components, is separated into individual electronic components. This method has the advantage that both the cavity frame and the first and second adhesive films can be prepared for a number of electronic components simultaneously at wafer level relatively inexpensively. Consequently, a number of tried-and-tested steps that are known from semiconductor technology can be used.

This is the case in particular if there is applied to the upper side of the semiconductor wafer a layer of photoresist which is subsequently patterned photolithographically to form spacers 19. In this photo-patterning, the circuit structures on the semiconductor chip can be kept completely free of photoresist and the contact areas can be kept partially free of photoresist to the extent necessary. For this purpose, a photoresist with the customary commercial abbreviation SU8 may be used. This can be patterned extremely finely, to create just at predetermined locations of the semiconductor chip a number of cavities subdivided by small webs. This allows an extremely small, miniaturized footprint to be produced. In the case of larger structures, printing techniques may also be used to create the spacers. In this connection, screen printing techniques or mask printing techniques, in which the spacers themselves are produced merely in the form of blocks while the regions necessary for the subsequent connection remain free of plastic, are of particular advantage.

In further embodiments not shown in the figures, the spacer is patterned so as to comprise a wall which has a breadth. The wall may have the form of a closed loop (also not shown in the figures). In this embodiment, the spacer may be described as having a concentrically located depression which produces a wall surrounding the depression.

Both the first adhesive film and the second adhesive film on the back sides of the semiconductor chips may consist of UV-precurable material and are irradiated with UV light before being separated by a diamond saw, in order to achieve fixing in the separating installation on the basis of the precuring by ultraviolet light. Over and above precuring purely by means of UV light, the first and second adhesive films may also be thermally curable. The corresponding thermal curing step may take place after the application of the semiconductor chip with the first adhesive film to inner areas of external contacts of a metal frame and before the bonding of the bonding connections. This ensures that displacement of the semiconductor chip is not possible during the bonding.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

### LIST OF REFERENCE NUMERALS

2 base module component
3 module component
7 circuit carrier
8 connecting element
10 semiconductor module
11 module component
12 edge region
14 bonding wires
18 back side
19 spacer
21 surface
23 terminal area
24 housing
27 contact area
28 contact via
29 external contact area
31 underside
32 film
50 channel
51 window
52 dashed line
53 semiconductor wafer
54 layer of plastic
55 adhesive film

What is claimed is:

1. A semiconductor component, comprising:
a first module component having a contact area on an upper surface thereof;
a second module component stacked on top of the first component, wherein the first and second module components are electrically connected to each other and/or to a higher-level circuit carrier by connecting elements: and
a spacer arranged between the first and second module components, wherein at at least one point, a spacing distance d between the spacer and the contact area is 0 μm<d<80 μm.

2. The semiconductor component of claim 1, wherein the spacing distance d is 0μm<d<40 μm.

3. The semiconductor component of claim 1, wherein the spacing distance d is 0 μm<d<20 μm.

4. The semiconductor component of claim 1, wherein the spacing distance d is 0 μm<d<10 μm.

5. The semiconductor component of claim 1, wherein the spacing distance d is 0 μm<d<5 μm.

6. The semiconductor component of claim 1, wherein the spacing distance d is 0 μm<d<1 μm.

7. The semiconductor component of claim 1, wherein the spacing distance d lies between the contact area and an outer side surface of the spacer.

8. The semiconductor component of claim 7, wherein the spacer comprises at least one wall of a photo-patternable material, the wall having a breadth, wherein outer side surfaces of the at least one wall provide the outer side surface of the spacer.

9. The semiconductor component of claim 8, wherein the wall comprises a continuous loop.

10. A semiconductor component, comprising:
a first module component having a contact area on an upper surface thereof;
a second module component stacked on top of the first component, wherein the first and second module components are electrically connected to each other and/or to a higher-level circuit carrier by connecting elements; and
a spacer arranged between the first and second module components, wherein at at least one point, the spacer covers a portion of the contact area while leaving a partial region of the contact area free.

11. The semiconductor component of claim 10, wherein, at at least one point in the spacer, a channel leads from the contact area to an edge region of the first module component, with a partial region of the upper surface of the first module component being left free of the spacer at a bottom of the channel.

12. The semiconductor component of claim 10, wherein the contact area is surrounded at least on one side by a partial region of the spacer in the manner of a finger.

13. The semiconductor component of claim 12, wherein the partial region of the spacer in the manner of a finger is spaced at a distance from the contact area, wherein at at least one point, a spacing distance d between an outer side surface of the spacer and the contact area is 0 μm<d<80 μm.

14. The semiconductor component of claim 13, wherein the spacing distance is 0 μm<d<40 μm.

15. A method for producing a semiconductor component, comprising:
providing a semiconductor wafer with a plurality of semiconductor chip positions and an active surface, each semiconductor chip position having an active surface with contact areas;
applying a photo-patternable material to the active surface of the wafer;
patterning the photo-patternable material to form a spacer on the active surface of each semiconductor chip position;
separating the semiconductor chip positions from the wafer to provide a plurality of lower module components, each having a spacer positioned on the active surface;
providing a plurality of upper module components, each having an active surface with contact areas;
mounting the lower module component on a higher-level circuit carrier;
producing electrical connections between the lower module carrier and the higher-level circuit carrier;
mounting one of the upper module components on the spacer of each of the lower module components; and
producing electrical connections between the upper module component and the higher-level circuit carrier.

16. The method of claim 15, wherein the photo-patternable material is applied by spin coating to produce a layer on the active surface of the semiconductor wafer.

17. The method of claim 15, wherein the photo-patternable material is patterned by photolithography.

18. The method of claim 15, wherein the photo-patternable material is patterned to produce a spacer with outer side surfaces that are spaced at a distance d from contact areas of the lower module component.

19. The method of claim 18, wherein at at least one point, the distance d between the outer side surface of the spacer and one of the contact areas of the lower module component is 0 μm<d<80 μm.

20. The method of claim 19, wherein the distance d is 0 μm<d<40 μm.

21. The method of claim 15, wherein the photo-patternable material is patterned to produce a spacer having a partial region in the manner of a finger which is positioned adjacent at least one of the contact areas of the lower module component.

22. The method of claim 15, wherein the upper module component is mounted on the spacer by double-sided adhesive film.

23. The method of claim 15, wherein the lower module component is mounted on the higher-level circuit carrier by double-sided adhesive film.

24. A method for producing a semiconductor component, comprising:
mounting a first module component on a carrier, the first module component having a contact area on an upper surface thereof;
forming a spacer above the first module component, the spacer having an outer side surface; and
stacking a second module component on top of the first module such that the spacer is arranged between the first and second module components,
wherein at at least one point, a spacing distance d between the outer side surface of the spacer and the contact area is 0 μm<d<80 μm or the contact area is partially covered by the spacer.
